(19) United States
(12) Patent Application Publication
(10) Pub. No.: US 2006/0081968 A1
(43) Pub. Date: Apr. 20, 2006

(54) Semiconductor package

(76) Inventors: Shwang Shi Bai, Hsinhua (TW); Jung Chung Chang, Hsinhua (TW); Pai Sheng Cheng, Hsinhua (TW); Chia Hui Wu, Hsinhua (TW)

Correspondence Address: SMITH, GAMBRELL & RUSSELL, LLP, 1850 M STREET, N.W., SUITE 800, WASHINGTON, DC, 20036, US

(21) Appl. No.: 10/964,725

(22) Filed: Oct. 15, 2004

(51) Int. Cl. H01L 23/02

(52) U.S. Cl. 257/678

(57) ABSTRACT

The present invention discloses a semiconductor package comprising a substrate having a plurality of substrate units, a plurality of semiconductor chips respectively disposed on the substrate units, and a plurality of conductive guard lines each disposed between two adjacent substrate units. Each substrate unit is provided with a plurality of contact pads and a plurality of conductive leads respectively connected to the corresponding contact pads. The semiconductor chips are electrically connected to the plurality of contact pads through the conductive leads. Each substrate unit has at least one of the contact pads electrically connected to the conductive guard lines such that the semiconductor package of the present invention can efficiently achieve the function of electrostatic discharge (ESD) protection.

### BACKGROUND OF THE INVENTION

1. Field of the Invention

This invention generally relates to a semiconductor package, and more particularly to a semiconductor package for liquid crystal display driver, which can efficiently achieve the function of electrostatic discharge (ESD) protection.

2. Description of the Related Art

In the prior art, liquid crystal display (LCD) or plasma display panels have been widely applied to many electronic products. Generally, either of these display panels has the outer leads of its display driver packages attached to the pads (or leads) disposed on the boundary portion of a lower glass substrate.

With the increasing requirements for more complicated electronic apparatuses, the speed and complexity of semiconductor chips have become relatively higher and higher. Accordingly, higher packaging efficiency for the semiconductor chips is required nowadays. The current packaging technology for driver ICs of the LCD panel includes chip on flex (COF) and tape automatic bonding (TAB), and these two technologies are mainly used for fine pitch LCD driver. The film BGA (ball grid array) packaging technology is widely utilized for memory packages. However, with the great requirements for display resolution, the I/O pins of packages are relatively increased. Under the principle of achieving light and thin packages, higher density IC packages are highly required.

Since the resolution of displays is becoming higher and higher, the numbers of the input/output ports need to be highly increased. Further, the driver ICs need to increase the resolution without increasing their number; that is, the circuit line or lead pitches are required to be decreased so as to meet the requirement of higher-resolution displays. For liquid crystal displays, reducing the driver ICs pitch is a trend for achieving the object of high resolution. Therefore, the TAB packaging technology will be limited in application; more specifically, the I/O leads pitch of the TAB package is not easy to meet the requirement of the higher-resolution displays. Although the COF package and the TAB package similarly utilize a flexible substrate as its package body, they present different characteristics due to their different structures. The COF package is thinner and lighter than the TAB package. In addition, the significant difference between both of them is the lead resolution, i.e. lead pitch. Besides, the inner leads of the TAB package stay floated and are not supported by a polyimide (PI) film; therefore, they are weak in mechanical strength and thus easy to become deformed. Generally, if the pitch is smaller than 40 μm, the COF package will be more reliable than the TAB package. Since the leads of the COF package, which are connected to a driver IC, are supported by a polyimide (PI) film and not floated, the COF package can obtain higher yield than TAB package does. In addition, the flexible substrate used for the flexible film package is required to be a two-layer adhesiveless substrate. In addition to the use of the two-layer adhesiveless substrate, the copper layer on the substrate is also required to be decreased in thickness so as to achieve a high density package. Under various substrate manufacturing technologies, the adhesiveless flexible substrate using sputtering deposition process to control the copper layer thickness can be well applied to the high density COF package.

However, the above-mentioned LCD driver IC packages have one disadvantage; that is, the substrate may induce static charge during transportation, particularly, transportation through sprocket holes and may even damage the IC packages due to over-large static electricity. Further, due to the restriction of IC face-down bonding, the static electricity induced around the connection of the inner leads and the IC chip can not be effectively dissipated by an ionizer. In the current technologies, most of the methods used for dissipating the static electricity are usually improved by IC layout design, i.e. by enhancement of the electrostatic discharge (ESD) design to protect the circuit. However, these methods will increase the complexity of IC design and manufacturing cost.

Accordingly, there exists a need for providing a semiconductor package to resolve the above-mentioned problems.

### SUMMARY OF THE INVENTION

The main object of the present invention is to provide a semiconductor package, which can resolve the static electricity problem caused during transportation.

The second object of the present invention is to provide a semiconductor package, which can efficiently improve package yield and reduce the complexity of IC design and manufacturing cost.

In order to achieve the object, the semiconductor package of the present invention comprises a substrate having a plurality of substrate units, a plurality of semiconductor chips respectively disposed on the substrate units, and a plurality of conductive guard lines each disposed between two adjacent substrate units. Each substrate unit is provided with a plurality of contact pads and a plurality of conductive leads respectively connected to the corresponding contact pads. The semiconductor chips are electrically connected to the plurality of contact pads through the conductive leads. Each substrate unit has at least one of the contact pads electrically connected to the conductive guard lines so as to dissipate the static electricity through the conductive guard lines, thereby the semiconductor package of the present invention can efficiently achieve the function of electrostatic discharge (ESD) protection.

According to one feature of the present invention, the plurality of contact pads include signal pads and ground pads; the guard lines are electrically connected to the ground pads but isolated from the signal pads. Further, the plurality of contact pads also include dummy pads electrically connected to the guard lines.

According to another feature of the present invention, the semiconductor package comprises two conductive supporting lines respectively disposed on two opposite sides of the substrate thereby enhancing the mechanical strength of the substrate, and a plurality of sprocket holes provided on the two conductive supporting lines. The plurality of substrate units are substantially arranged in a row and positioned between the two conductive supporting lines. In one embodiment of the present invention, the plurality of conductive guard lines are electrically connected to the conductive supporting lines so as to further dissipate the static electricity from the plurality of the conductive guard lines, thereby more efficiently achieving the function of electrostatic discharge (ESD) protection.

### BRIEF DESCRIPTION OF THE DRAWINGS

The embodiments of the present invention will be clearly described when taken in conjunction with the accompanying drawings.

FIG. 1 is a schematic top view of a conventional LCD driver IC package.

FIG. 2 is a sectional view of a COF package.

FIG. 3 is a sectional view of a TAB package.

FIG. 4 is a schematic top view of a LCD driver IC package according to one embodiment of the present invention.

### DETAILED DESCRIPTION OF THE PREFERRED EMBODIMENT

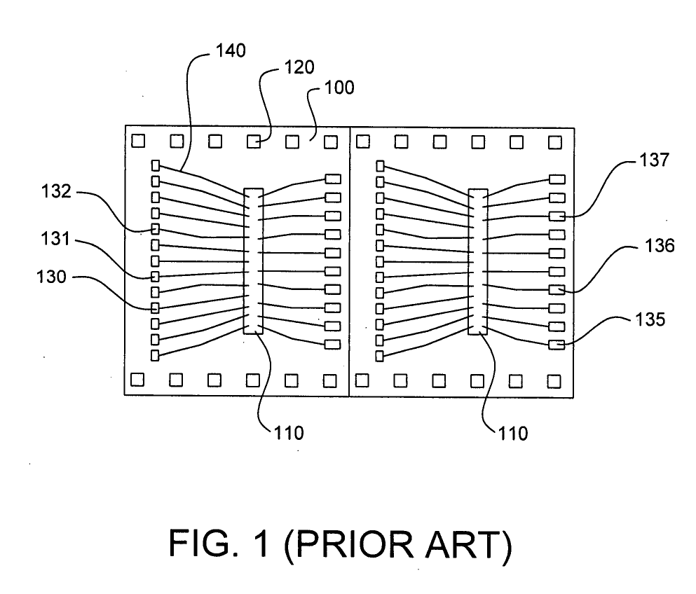

In order to better understand the features of the present invention, it is needed to illustrate the conventional LCD driver IC package. Referring to FIG. 1, a conventional LCD driver IC package mainly comprises a substrate 100, a semiconductor chip 110, a plurality of sprocket holes 120, and a plurality of contact pads 130, 131, 132, 135, 136 and 137. The substrate 100 has an upper surface and a lower surface, and is provided with the contact pads 130, 131, 132, 135, 136 and 137. These contact pads include signal pads, ground pads and dummy pads. For example, the contact pad 130 can be signal pad, the contact pad 131 can be ground pad, and the contact pad 132 can be dummy pad. The semiconductor chip 110 is disposed on the upper surface of the substrate 100 and electrically connected to the contact pads through conductive leads 140. The plurality of sprocket holes 120 are used for cooperating with the sprocket gear of a transporter (not shown) such that the IC package can be transported to a working position, for example, a predetermined position for the IC package punch.

However, the conventional IC package may induce electrostatic charge during transportation. The semiconductor chip 110 may be damaged while an over-large static electricity is induced. Further, due to the restriction of face-down bonding of the semiconductor chip 110, the static electricity induced around the connection of the inner leads and the IC chip can not be effectively dissipated by an ionizer. Therefore, in the current technologies, most of the methods used for dissipating the static electricity are usually improved by IC layout design, i.e. by enhancement of the electrostatic discharge (ESD) design to protect the circuit. However, these methods will greatly increase the complexity of IC design and manufacturing cost.

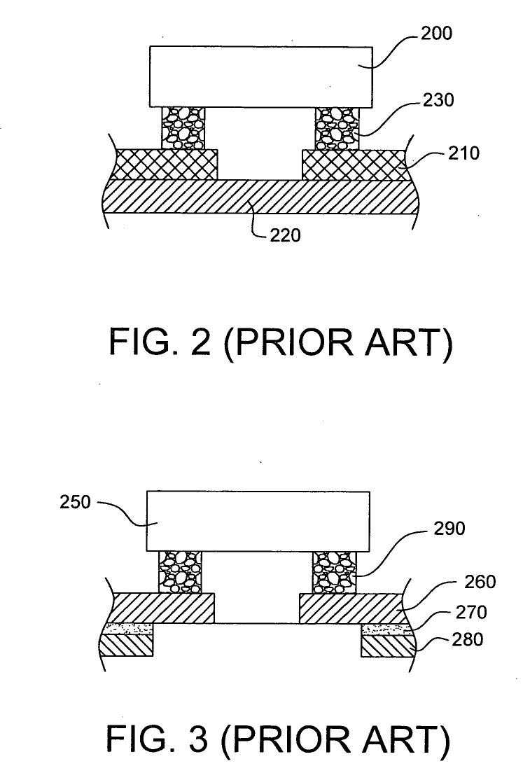

FIG. 2 is a sectional view of a COF (chip on flex) package. The COF package comprises a semiconductor chip 200 directly flip-chip attached on a flexible substrate, which is generally referred to as “COF substrate”. The COF substrate typically includes a polyimide (PI) film 220 and a copper layer 210 disposed on the PI film 220. Since the COF packaging technology is applied to directly attach a chip on a flexible substrate by flip chip process, the LCD driver IC package and some electronic components can be directly disposed on the film thereby saving the space of the conventional printed circuit board and further achieving the object of obtaining a light-weight and small-size assembly. In addition, this packaging technology focuses on the growth of gold bumps on the metal pads of the chip, the growth of bonding pads corresponding to the gold bumps on the substrate, and the attachment of the flip chip on the substrate by the steps of aligning the gold bumps with the bonding pads and then bonding them together. The flip chip attachment has several advantages such as short connection, best electrical property and high-density output/input pads.

FIG. 3 is a sectional view of a TAB (tape automatic bonding) package. The TAB package comprises a semiconductor chip 250 disposed on a TAB substrate. The TAB substrate includes a polymer layer 280, an adhesive layer 270 formed on the polymer layer 280 and a copper layer 260 formed on the adhesive layer 270. The semiconductor chip 250 is disposed on the copper layer 260. The TAB process is applied to attach a semiconductor chip to the metal lines (copper layer) formed on a polymer tape (polymer layer). The material of the polymer tape is preferably polyimide (PI), and the metal lines on the polymer tape are typically formed by copper (Cu). The TAB substrate has several advantages such as thin thickness, small pin pitch, and large number of output/input leads and therefore is very appropriate for being applied to light-weigh, small-size IC products, e.g. LCD driver IC package.

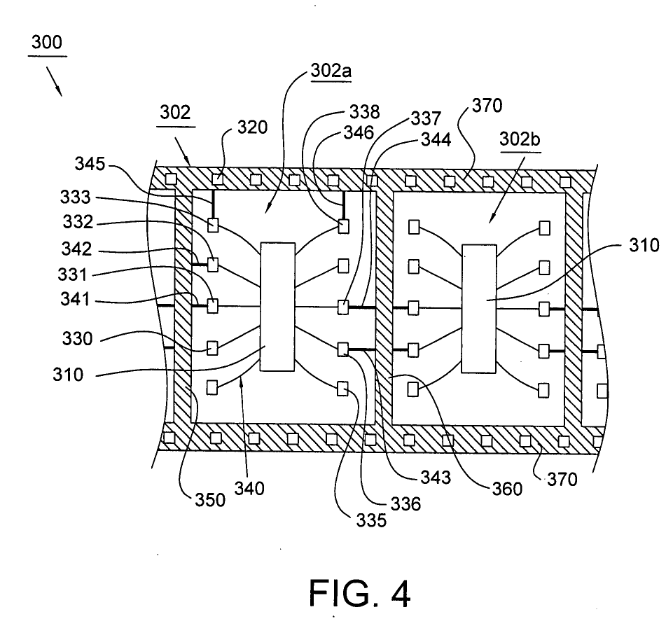

Referring to FIG. 4, it shows a semiconductor package 300 according to one embodiment of the present invention. The semiconductor package 300 includes a substrate 302 having a plurality of substrate units (only two substrate units 302a and 302b shown in FIG. 4), a plurality of semiconductor chip (only two semiconductor chips 310 shown in FIG. 4) respectively disposed on the substrate units 302a and 302b, and a plurality of conductive guard lines (only two conductive guard lines 350 and 360 shown in FIG. 4) each disposed between two adjacent substrate units. Each substrate unit is provided with a plurality of contact pads (e.g. contact pads 330, 331, 332, 333, 335, 336, 337 and 338 on the substrate unit 302a), a plurality of conductive leads 340 connected between the semiconductor chips 310 and the contact pads, and a plurality of connecting lines 341, 342, 343, 344, 345 and 346 connected between the contact pads and the conductive guard lines. The guard lines 350 and 360 and the connecting lines 341, 342, 343, 344, 345 and 346 can be metal lines, which are directly formed on the substrate by lithography. The semiconductor chips 310 can be LCD driver IC chips for driving LCD panels. The plurality of contact pads can includes signal pads, ground pads and dummy pads. For example, the contact pad 330 can be signal pad, the contact pad 331, 333 can be ground pad, and the contact pad 332, 338 can be dummy pad.

It should be noted that the contact pad (ground pad) 331 is electrically connected to the guard line 350 through the connecting line 341, and the contact pad (signal pad) 330 is not connected to the guard line 350; that is, the contact pad (signal pad) 330 is isolated from the guard line 350. The contact pad (dummy pad) 332 can either be electrically connected to the guard line 350 through the connecting line 342, or not connected to the guard line 350. Preferably, the contact pad (dummy pad) 332 is electrically connected to the guard line 350 through the connecting line 342. Therefore, the electrostatic charge induced on the semiconductor package during transportation can be dissipated through the guard line 350 to a grounded transporter (not shown), thereby preventing an over-large static electricity from damaging the semiconductor chips 310.

According to the semiconductor package of the present invention, the semiconductor package 300 can also comprises two conductive supporting lines 370 respectively disposed on two opposite sides of the substrate 302 thereby enhancing the mechanical strength of the substrate 302. The conductive supporting lines 370 can be a metal layer, such as a tin (Sn) layer or a gold (Au) layer, formed on the substrate 302. A plurality of sprocket holes 320 are formed on the two conductive supporting lines 370. The plurality of substrate units (only two substrate units 302a and 302b shown in FIG. 4) are substantially arranged in a row and positioned between the two conductive supporting lines 370. It should be noted that the contact pad (ground pad) 333 is electrically connected to the conductive supporting lines 370 through the connecting line 345. The contact pad (dummy pad) 338 can either be electrically connected to the conductive supporting lines 370 through the connecting line 346, or not connected to the conductive supporting lines 370. Preferably, the contact pad (dummy pad) 338 is electrically connected to the conductive supporting lines 370 through the connecting line 346. The guard lines 350 and 360 according to the present invention can be electrically connected to the conductive supporting lines 370. Therefore, the electrostatic charge induced on the semiconductor package during transportation can be introduced to the sprocket gear of the transporter (not shown) through the guard line 350 and the conductive supporting lines 370, thereby more effectively protecting the semiconductor chips 310 from being damaged by static electricity. The connecting lines, e.g. connecting lines 341, 342, 343, 344, 345 and 346, according to the present invention can be electrically connected to “dummy pad(s)” or “ground pad(s)” and introduce the static electricity to the grounded transporter (not shown) through the conductive guard line 350 and the conductive supporting lines 370, thereby preventing an over-large static electricity from damaging the semiconductor chips 310.

Besides, the guard lines 350 and the connecting lines 341, 342, 343, 344, 345 and 346 according to the present invention can be formed together with other circuit patterns (e.g. conductive leads and contact pads) on the substrate by lithography; therefore, no extra mask design or process is needed. Further, since the electrostatic charge problem can be resolved in the packaging process rather than in the IC circuit design, the semiconductor package according to the present invention can greatly improve the product yield, shorten the manufacturing time and reduce the manufacturing cost.

Although the preferred embodiments of the invention have been disclosed for illustrative purposes, those skilled in the art will appreciate that various modifications, additions and substitutions are possible, without departing from the scope and spirit of the invention. For example, although the TAB package and COF package for LCD driver are well described in the above embodiments, the present invention can be applied to any semiconductor package having a similar substrate, e.g. film BGA (ball grid array) package. Therefore, the protection scope of the present invention will be defined in the accompanying claims.

1. A semiconductor package comprising:
a substrate having a plurality of substrate units, each substrate unit provided with a plurality of contact pads and a plurality of conductive leads respectively connected to the corresponding contact pads;
a plurality of semiconductor chips respectively disposed on the substrate units, each semiconductor chip electrically connected to the plurality of contact pads through the conductive leads; and
a plurality of conductive guard lines each disposed between two adjacent substrate units, wherein each substrate unit has at least one of the contact pads electrically connected to at least one of the conductive guard lines;
wherein the plurality of contact pads include a plurality of signal pads and a ground pad; and
wherein the signal pads are isolated from the conductive guard lines while the ground pad is electrically connected to one of the conductive guard lines.

2. (canceled)

3. The semiconductor package as claimed in claim 1, wherein the plurality of the contact pads further include a dummy pad, and the at least one of the conductive guard lines is electrically connected to the dummy pad.

4. The semiconductor package as claimed in claim 1, wherein the substrate is selected from a group of chip on flex (COF) substrate, tape automatic bonding (TAB) substrate and film ball grid array (film BGA) substrate.

5. The semiconductor package as claimed in claim 1, further comprising two conductive supporting lines respectively disposed on two opposite sides of the substrate for enhancing the mechanical strength of the substrate, and a plurality of sprocket holes formed on the two conductive supporting lines, wherein the plurality of substrate units are substantially arranged in a row and positioned between the two conductive supporting lines and at least one of the conductive guard lines is electronically connected to at least one of the conductive supporting line.

6. A semiconductor package comprising:
a substrate having a plurality of substrate units, each substrate unit provided with a plurality of contact pads and a plurality of conductive leads respectively connected to the corresponding contact pads;
a plurality of semiconductor chips respectively disposed on the substrate units, each semiconductor chip electrically connected to the plurality of contact pads through the conductive leads; and
a first conductive supporting line disposed on a first side of the substrate, wherein each substrate unit has at least one of the contact pads electrically connected to the first conductive supporting line;
wherein the plurality of contact pads include a plurality of signal pads and a ground pad; and
wherein the signal pads are isolated from the ground pad while the ground pad is electrically connected to the first conductive supporting line.

7. (canceled)

8. The semiconductor package as claimed in claim 6, wherein the plurality of the contact pads further include a dummy pad, and the first conductive supporting line is electrically connected to the dummy pad.

9. The semiconductor package as claimed in claim 6, wherein the substrate is selected from a group of chip on flex (COF) substrate, tape automatic bonding (TAB) substrate and film ball grid array (film BGA) substrate.

10. The semiconductor package as claimed in claim 6, further comprising a second conductive supporting line disposed on a second side of the substrate and opposite to the first conductive supporting line, wherein each substrate unit has at least one of contact pads electrically connected to the second conductive supporting line.

11. A semiconductor package comprising:
a flexible substrate;
a semiconductor chip disposed on the flexible substrate;
a first conductive supporting line disposed on a first side of the flexible substrate and electrically coupled to ground, wherein the semiconductor chip is electrically coupled to the first conductive supporting line; and
a plurality of sprocket holes formed on the first conductive supporting line for cooperating with a sprocket gear in a transporter, wherein an electrostatic charge induced on the semiconductor package is introduced to the sprocket gear through the first conductive supporting line.

12. (canceled)

13. The semiconductor package as claimed in claim 11, wherein the flexible substrate comprise a dummy pad electrically connected to the first conductive supporting line.

14. The semiconductor package as claimed in claim 11, wherein the flexible substrate is selected from a group of chip on flex (COF) substrate, tape automatic bonding (TAB) substrate and film ball grid array (film BGA) substrate.

15. (canceled)

16. The semiconductor package as claimed in claim 11, further comprising a second conductive supporting line disposed on a second side of the flexible substrate and opposite to the first conductive supporting line.

17. The semiconductor package as claimed in claim 11, further comprising a first conductive guard line disposed on a second side of the flexible substrate and adjacent to the first conductive supporting line.

18. The semiconductor package as claimed in claim 17, further comprising a second conductive guard line disposed on a third side of the flexible substrate and opposite to the first conductive guard line.

19. The semiconductor package as claimed in claim 18, further comprising a second conductive supporting line disposed on a fourth side of the flexible substrate and opposite to the first conductive supporting line.

20. The semiconductor package as claimed in claim 17, wherein the first conductive supporting line is electrically coupled to the first conductive guard line.

21. The semiconductor package as claimed in claim 11, further comprising:
a plurality of contact pads formed on the flexible substrate and electrically connected to the semiconductor chip, wherein the plurality of contact pads include a plurality of signal pads and a ground pad, and the signal pads are isolated from the first conductive supporting line while the ground pad is electrically connected to the first conductive supporting line.
